(19) United States
(12) Patent Application Publication
(10) Pub. No.: US 2009/0001599 A1
(43) Pub. Date: Jan. 1, 2009

(54) DIE ATTACHMENT, DIE STACKING, AND WIRE EMBEDDING USING FILM

(75) Inventors: Sally Foong, Milpitas, CA (US); Tan Kiah Ling, Bayan Lepas (MY); Cheng Sim Kee, Bayan Lepas (MY); Seshasayee Gaddamraja, Santa Clara, CA (US); Yue Ho Foong, Bayan Lepas (MY)

Correspondence Address: AMIN, TUROCY & CALVIN, LLP, 127 Public Square, 57th Floor, Key Tower, CLEVELAND, OH, 44114, US

(73) Assignee: SPANSION LLC, Sunnyvale, CA (US)

(21) Appl. No.: 11/770,239

(22) Filed: Jun. 28, 2007

(51) Int. Cl. H01L 23/49; H01L 21/58

(52) U.S. Cl. 257/777; 257/782; 438/109; 438/113; 257/E23.024; 257/E21.505

(57) ABSTRACT

Systems, methods, and/or devices that facilitate stacking dies in a multi-die stack using film over wire and attaching a die to a substrate are presented. Film over wire (FOW) techniques can be employed to facilitate stacking dies that are the same or similar in size such that the wires bonded onto the lower die can be embedded in film used to attach the two dies. FOW techniques can also be employed to embed a smaller die and wires attached thereto in film underneath a larger die stacked on top of the lower die such that the larger die can be supported by the film in areas where the larger die would otherwise overhang. Die attach film can be utilized to facilitate attaching a die to a substrate such that all areas between the die and substrate are filled thereby reducing or eliminating delamination.

### BACKGROUND

The increase in density of integrated circuit (IC) devices in recent years has resulted in the creation of multi-chip IC devices that can contain multiple active dies or chips in a single IC device, where the dies can be stacked vertically and connected electrically to a substrate, thereby increasing the number of electronic components (e.g., transistors) that can be included in a single package.

There can be instances where it is desirable to have two dies that are the same or similar size stacked with one die directly on top of the other die. However, wirebonding issues can arise with such an arrangement due to the pads on the lower die, on which wires can be attached, being covered by the upper die. Conventional methods have been employed to allow such a die arrangement, but with such conventional methods, problems can arise, as there can be wirebonding issues (e.g., broken wires), die chipping, and other issues. Further, such conventional methods can utilize more space in the chip package than may be desired.

In addition, wirebonding issues can also arise when two dies that are of significantly different size are to be stacked together in the same chip package. For example, if a smaller die is stacked on a significantly larger die, which is attached to a substrate, the wires going from the substrate to the smaller die may have to be longer than desired, due to the size of the lower, larger die, which can result in wirebonding issues such as wire breakage and/or short circuiting, as may be caused by a shock force to the device. Furthermore, issues can arise with delamination or voids associated with attachment of a die to a substrate due to materials that cannot withstand cure cycles associated with top die stacking, for example.

It is desirable to be able to minimize or reduce wirebonding issues, chip warping and breaking issues, spatial issues, as well as other issues, associated with multi-die stacks having adjacent dies of the same or similar size, dies that have significantly different sizes, and/or thin dies. Further, it is desirable to reduce or eliminate die attach delamination and voids that can result from cure cycles associated with top die stacking.

### SUMMARY

The following presents a simplified summary of the innovation in order to provide a basic understanding of some aspects described herein. This summary is not an extensive overview of the disclosed subject matter. It is intended to neither identify key or critical elements of the disclosed subject matter nor delineate the scope of the subject innovation. Its sole purpose is to present some concepts of the disclosed subject matter in a simplified form as a prelude to the more detailed description that is presented later.

The disclosed subject matter relates to systems and/or methods for stacking dies in a multi-die chip package using film over wire (FOW) as well as multi-die chip devices that can include FOW. In accordance with one aspect of the disclosed subject matter, multiple dies having a same or similar size can be stacked adjacent to each other without a spacer by using film that can adhere the two dies and embed the wirebonding on the lower die. For example, a first die can be adhered to the substrate or another die situated underneath the first die. Wirebonding of the first die can be performed to electrically connect wires to an active side of the first die, as desired. A film can be placed on the bottom side of a second die, which can be the non-active side of the die, and suitable levels of heat and pressure can be applied to the second die as the second die is placed on top of the first die, such that the film can mold itself over and around the wirebonding of the first die to embed the wires in the film (e.g., FOW film) without harming the wirebonding and the film facilitates adhering the second die to the first die as well. When the second die is adhered to the first die and the wirebonding is embedded, as desired, the heat and pressure can be removed, and curing can be performed on the two dies to complete the attachment. The amount of film used to attach the two dies and embed the wirebonding can be such that there is enough film to embed the wirebonding and provide a layer of film that can be a buffer region between the wirebonding and the die layer attached above.

In accordance with one aspect of the disclosed subject matter, a first die that is significantly larger than a second die can be placed on top of the second die in a multi-die stack by using film that can adhere the two dies, embed the wires connected to the lower die and the lower die, provide support for the larger upper die where the portions of the larger upper die overhang beyond the smaller lower die, and provide an additional buffer region between the wirebonding of the lower die and the upper die.

In accordance with yet another aspect of the disclosed subject matter, a bottom die can be attached to a substrate using die-attach film such that delamination and voids can be reduced or eliminated. Typically, a substrate can have traces and/or other components that appear on the side of the substrate where a die can be attached. To attach a die to the substrate, a die-attach film can be applied to the bottom side of the die. The die can then be attached or adhered to the substrate by applying a suitable amount of heat and pressure such that the die-attach film can mold itself over the traces and/or components on the surface of the substrate, where the die-attach film can embed the traces and/or components so as to substantially fill any voids that may be caused by the traces and/or components being raised above the substrate. The heat and pressure can be removed once the die is attached, and a curing process can be performed to complete the attachment of the die to the substrate.

The following description and the annexed drawings set forth in detail certain illustrative aspects of the disclosed subject matter. These aspects are indicative, however, of but a few of the various ways in which the principles of the innovation may be employed and the disclosed subject matter is intended to include all such aspects and their equivalents. Other advantages and distinctive features of the disclosed subject matter will become apparent from the following detailed description of the innovation when considered in conjunction with the drawings.

### BRIEF DESCRIPTION OF THE DRAWINGS

FIG. 1 illustrates a cross-section diagram of a multi-die device in accordance with an embodiment of the disclosed subject matter.

FIG. 2 illustrates a cross-section diagram of a multi-die device in accordance with another embodiment of the disclosed subject matter.

FIG. 3 illustrates a cross-section diagram of a device in accordance with yet another embodiment of the disclosed subject matter.

FIG. 4 illustrates a block diagram of a system that facilitates forming a semiconductor device in accordance with the disclosed subject matter.

FIG. 5 illustrates a block diagram of a die attach component in accordance with the disclosed subject matter.

FIG. 6 illustrates a methodology for attaching dies in accordance with the disclosed subject matter.

FIG. 7 illustrates a methodology for attaching a die to a substrate in accordance with the disclosed subject matter.

FIG. 8 illustrates another methodology for attaching a die to a substrate in accordance with the disclosed subject matter.

FIG. 9 illustrates a methodology for stacking dies in accordance with the disclosed subject matter.

FIG. 10 illustrates another methodology for stacking dies in accordance with the disclosed subject matter.

### DETAILED DESCRIPTION

The disclosed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the disclosed subject matter may be practiced without these specific details. In other instances, well-known structures and devices are shown in block diagram form in order to facilitate describing the subject innovation.

The increase in density of integrated circuit (IC) devices in recent years has resulted in the creation of multi-chip IC devices that can contain multiple active dies or chips in a single IC device, where dies can be stacked on top of each other thereby increasing the number of electronic components (e.g., transistors) that can be included in a single package. Issues (e.g., wire breakage, short circuiting of wires, chip warping, chip breakage, etc.) can arise when stacking dies, where, for example, an upper die is larger than a lower die such that the upper die has areas that overhang where the upper die is not supported, or when support is not provided in the center of the upper die, the upper die may sag. Conversely, wirebonding issues can also arise where a smaller die is stacked on top of a larger die due to the length of the wires connecting the smaller die to the substrate. Further, stacking a die on top of another die where the dies are of the same or similar size can raise wirebonding issues, as the pads on which the wires are connected for the lower die can be covered by the upper die, since it is of same or similar size.

Systems, methods, and devices relating to multi-die stacking are presented. The disclosed subject matter can employ film over wire (FOW) techniques to facilitate stacking dies of the same or similar size such that FOW film can be applied to the bottom side of the upper die, and applying suitable levels of heat and pressure, wires bonded on the lower die can be embedded into the film as the film molds itself over the wires, and the film facilitates attaching the two dies together. Further, FOW can be employed to embed a smaller lower die and wires bonded thereon within and under a larger die, such that the film can provide desired support to the upper die in areas of the upper die that would otherwise overhang without the film, due to the upper die being larger than the lower die. Moreover, die-attach film can be applied to a die to facilitate attaching the die to a substrate such that the die-attach film molds itself to fill in all areas between the die and the substrate to reduce or eliminate delamination.

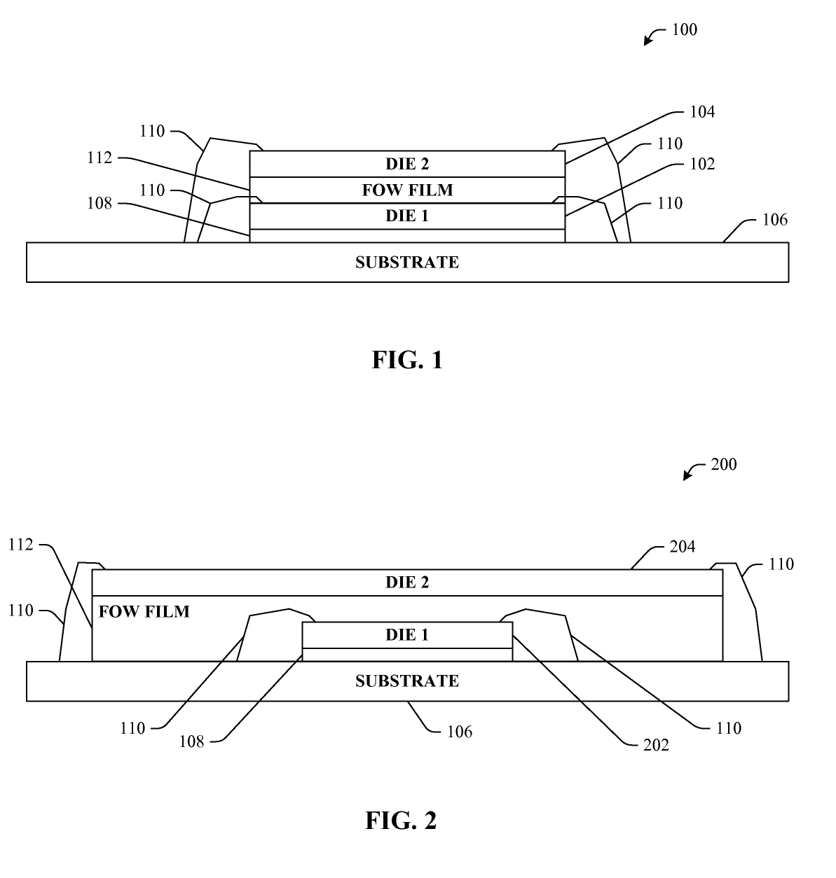

Now turning to the figures, FIG. 1 depicts a cross-section diagram of a multi-die device 100 in accordance with an embodiment of the disclosed subject matter. Device 100 can be a multi-die device that can include more than one die. For example, device 100 can include a first die 102 and a second die 104 that each can be electrically connected to a substrate 106. It is to be appreciated that, while two dies are shown for example purposes, the disclosed subject matter is not so limited. The disclosed subject matter contemplates that any number of dies can be included in device 100. In accordance with one embodiment of the disclosed subject matter, the two dies 102, 104 can be the same size, or substantially the same size, in length and/or width. Each die 102, 104 can be a semiconductor chip that can have an active side and a non-active side.

Substrate 106 can have traces (not shown) located on one side. The traces can be electrically conductive and can be formed on the substrate 106 by any suitable means, such as by etching processes (e.g., wet etching, dry etching, etc.) performed on the substrate surface or deposition processes (physical vapor deposition, chemical vapor deposition, electrochemical deposition, etc.).

The first die 102 can be adhered to the side of the substrate 106 having the traces by laminating the first die with a die-attach film 108 that can be comprised of an insulating adhesive material, for example. The film 108 can be applied to the bottom (e.g., non-active side) of the first die 102, and the first die 102 can then be adhered to substrate 106. To facilitate adhering the first die 102 to the substrate 106, heat can be applied to the film 108, and/or pressure can be applied to the first die 102 and/or film 108, so that the film 108 can be malleable (e.g., in a semi-fluid state) such that the film 108 can mold itself around the traces and can form a bond with the substrate 106 such that there are no gaps (e.g., voids, spaces, abscesses), or substantially no gaps, between the film 108 and the first die 102 and between the film 108 and the substrate 106 and traces formed thereon. Further, the film 108 can be applied such that it can reduce or eliminate delamination between the first die 102 and the substrate 106. Once the die 102 is attached to the substrate 106, the heat and/or pressure can be removed to allow the film 108 to cure (e.g., soft cure). Further curing can be performed as desired to facilitate the attachment of the die 102 and the substrate 106. For example, soft curing can be performed such that the film 108 is permitted to set for a period of time, as desired. Also, hard curing can be performed to heat the film 108 (and device 100, or parts thereof) at a desired temperature level for a desired period of time to complete the setting of the film 108. For example, device 100, or parts thereof, can be placed in an oven that can supply the desired heat level to cure the device 100.

A plurality of wires 110 can be employed to electrically connect the first die 102 to the substrate 106. The wires 110 can be formed of any conductive material (e.g., gold). A desired number of wires 110 can be connected electrically to the substrate 106 by bonding one end of each of the wires 110 correspondingly to the desired traces on the substrate 106. The other end of each of the wires 110 can be bonded correspondingly to pads (not shown) on the active side of the first die 102.

The second die 104 can be adhered to the first die 102 by laminating the second die 104 with FOW film 112 that can be applied to the bottom side (e.g., non-active side) of the second die 104, such that the film 112 can form over or around the wires 110 (e.g., FOW) that can be bonded to the pads on the first die 102 so that such wires 110 can be embedded in the film 112. To facilitate adhering the second die 104 to the first die 102 and embedding the wires 110 connected thereon, heat can be applied to the film 112, and/or pressure can be applied to the second die 104 and/or film 112, so that the film 112 can be malleable such that the film 112 can mold itself around the wires 110 and can form a bond with the first die 102 such that there are no gaps, or substantially no gaps, between the film 112 and the second die 104 and between the film 112 and the first die 102 and the wires 110 bonded thereon.

The heat can be applied to the second die 104 and transferred to the film 112 via the second die 104, when the second die 104 is such that it will not be harmed by having such heat applied to it. Where such heat may cause harm to the second die 104, the heat can be applied directly to the film 112, instead. The heat and pressure that can be applied can be at such respective levels that the dies 102, 104 and the wires 110 are not harmed as the dies 102, 104 are attached to each other and the wires 110 associated with the first die 102 are embedded in the film 112.

The amount of FOW film 112 that can be applied to adhere the second die 104 and the first die 102 and embed the wires 110 connected to the first die 102 can be such that there is a sufficient margin between the embedded wires 110 and the bottom side of the second die 104 so that the embedded wires 110 are not likely to be harmed by the second die 104 above. For example, if the wires 110 bonded to the first die extend to a height of approximately sixty microns over the first die 102, the film 112 can have a thickness (e.g., height) of approximately seventy-five microns so that there can be a buffer region between the top (e.g., highest point) of the wires 110 and the bottom of the second die 104. A desired number of wires 110 can be bonded to pads on the top side (e.g., active side) of the second die 104. As a result, the overall size of the device 100 can be reduced, since the thickness of the film 112 can result in less space between two dies (e.g., 102, 104) than conventional implementations relating to dies of the same or similar size being included in the same chip package.

By employing FOW film 112 to embed the wires 110 bonded on the first die 102, the wires 110 can be provided additional support by the film 112 which can protect the wires 110 from breakage or shorting that may otherwise have been caused due to shock to the device 100 (e.g., from dropping or hitting the device 100). Further, the FOW film 112 can facilitate adhering two dies (e.g., 102, 104) of the same or similar size positioned adjacent to each other as well as the wirebonding of the lower die (e.g., 102). Where two dies are of the same of similar size and are placed adjacent to each other (e.g., one die on top of the other), wirebonding can be an issue because the pads on the lower die may not extend out beyond the area covered by the upper die.

There can be other ways of stacking similar or same size dies on top of each other, such as by placing a spacer or other object in between the two dies such that the pads of the lower die can be exposed and there is room between the two dies to facilitate wirebonding of the lower die. However, that may cause the upper die to have some overhang, which can be an issue as such overhang may lack the desired support, and the wirebonding of the upper die may then be subject to shock or other forces that can cause the unsupported overhanging region to bounce resulting in wire breakage or short circuiting. Instead, by employing FOW film 112 to embed the wires of the lower die 102, the use of a spacer is obviated, the desired support can be provided to the upper die 104, and the FOW film 112 can reduce or minimize wirebonding issues for both the upper die 104 and lower die 102.

It should be noted that, while device 100 is shown in FIG. 1 with one wire on each side of dies 102 and 104, each of dies 102 and 104 can have any desired number of wires 110. Further, while the wires 110 are shown on two sides of the dies 102 and 104, it is to be appreciated that each die 102, 104 can have pads on all sides of the die to facilitate wirebonding on all sides of the respective die. In addition, while first die 102 is shown as being attached to substrate 106 with die-attach film 108, it is to be appreciated that additional dies can be employed, as desired. For example, first die 102 can be stacked on top of another die (not shown) using die-attach film 108 (or FOW film 112 if wires of the other die may be embedded), and that other die can be attached to the substrate 106 using die-attach film 108.

Further, it is to be appreciated that, while die-attach film 108 can be employed to attach a die (e.g., 102) to a substrate 106, FOW film 112 can also be used to attach a die to the substrate 106. It should also be noted that well known structures have not been shown in order not to unnecessarily obscure the subject innovation.

Turning to FIG. 2, illustrated is a cross-section diagram of a multi-die device 200 in accordance with another embodiment of the disclosed subject matter. Device 200 can be a multi-die device that can include more than one die. For example, device 200 can include a first die 202 and a second die 204 that each can be electrically connected to a substrate 106. It is to be appreciated that, while two dies are shown for example purposes, the disclosed subject matter is not so limited. The disclosed subject matter contemplates that any number of dies can be included in device 200. In accordance with an embodiment of the disclosed subject matter, the first die 202 can be smaller in size, such as in length and/or width, than the second die 204. Each die 202, 204 can be a semiconductor chip that can have an active side that can be electrically connected to the substrate 106 and a non-active side.

Using die-attach film 108, the first die 202 can be laminated with the die-attach film 108 and can be adhered to the side of the substrate 106 having the traces formed thereon. The film 108 can be applied to the bottom (e.g., non-active side) of the first die 202, and the first die 202 can then be adhered to substrate 106. To facilitate adhering the first die 202 to the substrate 106, heat can be applied to the film 108, and/or pressure can be applied to the first die 202 and/or film 108, so that the film 108 can be malleable such that the film 108 can mold itself around the traces and can form a bond with the substrate 106 such that there are no gaps, or substantially no gaps, between the film 108 and the first die 202 and between the film 108 and the substrate 106 and traces formed thereon. Applying the film 108 such that no gaps, or substantially no gaps, appear between the first die 202 and substrate 106 can reduce or eliminate delamination between the first die 202 and the substrate 106. The heat can be applied to the film 108 via a die-attach tool (not shown) that can place a die (e.g., 102, 104, 202, 204) in the desired place while applying heat which can transfer directly to the film 108. However, if applying such heat to the second die 204 may cause harm to the second die 204, then the heat can be applied directly to the film 108.

Once the die 102 is attached to the substrate 106, the heat and/or pressure can be removed to allow the die-attach film 108 to cure (e.g., soft cure). Further curing can be performed as desired to facilitate the attachment of the die 102 and the substrate 106.

The first die 202 can have wires 110 bonded onto the die 202, as desired, to electrically connect the first die 202 to the substrate 106. The desired number of wires 110 can be connected electrically to the substrate 106 by bonding one end of each of the wires 110 correspondingly to the desired traces on the substrate 106. The other end of each of the wires 110 can be bonded correspondingly to pads (not shown) on the active side of the first die 202.

The second die 204 can be adhered to the first die 202 by laminating the bottom side (e.g., non-active side) of the second die 204 with FOW film 112. As the second die 204 is attached to the first die 202, the FOW film 112 can form over or around the wires 110 (e.g., FOW) that can be bonded to the pads on the first die 202 so that such wires 110 can be embedded in the FOW film 112. To facilitate adhering the second die 204 to the first die 202 and embedding the wires 110 connected thereon, heat can be applied to the film 112, and/or pressure can be applied to the second die 204 and/or film 112, so that the film 112 can be malleable such that the film 112 can mold itself around the wires 110 and can form a bond with the first die 202 such that there are no gaps, or substantially no gaps, between the film 112 and the second die 204 and between the film 112 and the first die 202 and the wires 110 bonded thereon. The heat and pressure that can be applied can be at such respective levels that the dies 202, 204 and the wires 110 are not harmed as the dies 202, 204 are attached to each other and the wires 110 associated with the first die 202 are embedded in the film 112.

The amount of FOW film 112 that can be applied to adhere the second die 204 and the first die 202 and embed the wires 110 connected to the first die 202 can be such that the first die 202, and wires 110 bonded thereon, can be embedded or encapsulated by the film 112, where the film 112 can extend from the bottom of the second die 204 to the substrate 106 in those regions where the second die 204 extends beyond (e.g., overhangs) the first die 202 and to the first die 202 in those regions of the second die 204 where the second die 204 is situated above the area of the first die 202. Further, there can be sufficient film 112 so that there can be a sufficient margin between the embedded wires 110 and the bottom side of the second die 204. For example, the film 112 can have a thickness (e.g., height) of approximately 170 microns (in the area where the second die 204 overhangs when attached to the first die 202) so that the smaller die 202 can be completely encapsulated by the film 112 and so there can be a buffer region between the top (e.g. highest point) of the wires 110 and the bottom of the second die 204 in order to reduce or eliminate the risk of damage to the wires 110 by the second die 204. A desired number of wires 110 can be bonded to pads on the top side (e.g., active side) of the second die 104. Those wires 110 can be electrically connected to the substrate 106.

By employing FOW film 112 and encapsulating the much smaller die 202 in film 112 under the larger die 204, the overall size of the device 200 can be reduced, since the thickness of the film 112 can be such that it can result in less space between two dies (e.g., 202, 204) than conventional implementations relating to multi-stack die packages. Further, embedding or encapsulating the smaller die 202 in film 112 under larger die 204 can facilitate wirebonding and reduce or minimize wire malfunctions (e.g., wire breaking, short circuits) and facilitate a more desirable circuit layout. For example, it may be desirable to have a smaller die (e.g., 202) under a larger die (e.g., 204), for reasons such as ease of circuit layout and/or to minimize wirebonding issues. For example, if the smaller die is stacked on top of a much larger die, wirebonding issues can arise when wirebonding between the substrate 106 and the smaller die, since the wires 110 would have to extend from the substrate 106 over the larger die and then extending across the larger die to reach the pads of the smaller die. Instead, embedding the wires 110 of the smaller die 202 and the die 202 itself in FOW film 112 can provide improved support to the wires 110, which can reduce or minimize wire breakage and short circuits.

There can be other ways of stacking a larger die on top of a smaller die, such as by placing a spacer or other object on each side of the smaller die such that the pads of the smaller die can be exposed and there is room between the two dies to facilitate wirebonding of the smaller, lower die. However, depending on the implementation that may cause the larger, upper die to have some unsupported overhang, which can be an issue as such overhang may lack the desired support, and the wirebonding of the upper die may then be subject to shock or other forces that can cause wire breakage or short circuiting of the wires. Further, the larger, upper die above may not have adequate support towards the middle of the upper die, which may cause the upper die to sag in the center due to the lack of support, particularly if the device is subject to a shock force.

Instead, by employing FOW film 112 to embed the wires 110 of the smaller, lower die 202 as well as the lower die 202 itself, the use of a spacer(s) is obviated, the desired support can be provided to the upper die 204, and the FOW film 112 can reduce or minimize wirebonding issues for both the larger, upper die 204 and smaller, lower die 202. Further, by employing FOW film 112, additional procedures (e.g., creating spacers, attaching spacers) that may be involved in using spacer(s) can be obviated.

It should be noted that, while device 200 is shown in FIG. 2 with one wire 110 on each side of dies 202 and 204, each of dies 202 and 204 can have any desired number of wires 110. Further, while the wires 110 are shown on two sides of the dies 202 and 204, it is to be appreciated that each die 202, 204 can have pads on all sides of the respective die (e.g., 202, 204) to facilitate wirebonding on all sides of the respective die. In addition, while first die 202 is shown as being attached to substrate 106 with die-attach film 108, it is to be appreciated that additional dies can be employed, as desired. For example, first die 202 can be stacked on top of another die (not shown) using die-attach film 108 (or FOW film 112, if wires 110 bonded to the other die are being embedded), and that other die can be attached to the substrate 106 using die-attach film 108. Further, the overhanging regions of die 204 can have FOW film 112 applied to its bottom side in such a thickness so as to have the FOW film 112 extend to the other die to which the first die 202 is attached to encapsulate or embed the first die 202 in the FOW film 112. It should also be noted that well known structures have not been shown in order not to unnecessarily obscure the subject innovation.

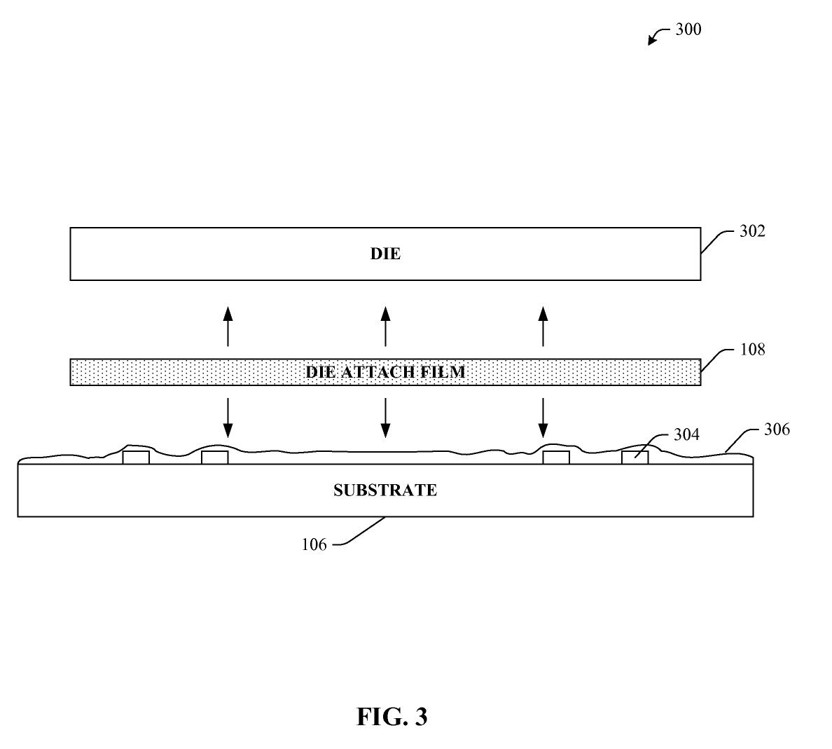

Turning to FIG. 3, illustrated is a cross-section diagram of a device 300 in accordance with yet another embodiment of the disclosed subject matter. Device 300 can be a device, such as a semiconductor device that can have a die 302 that can be connectively (e.g., physically and electrically) attached to a substrate 106. While device 300 is shown with only one die 302, for purposes of example, it is to be appreciated that the disclosed subject matter is not so limited. The disclosed subject matter contemplates that any number of dies can be included in device 300. Further, the die 302 can be a semiconductor chip that can have an active side and a non-active side.

The substrate 106 can have a desired number of traces 304 formed thereon. The traces 304 can be formed on the substrate 106 by any suitable means, such as by etching processes (e.g., wet etching, dry etching, etc.) performed on the substrate surface or deposition processes (physical vapor deposition, chemical vapor deposition, electrochemical deposition, etc.). Further, the traces 304 can be electrically conductive to facilitate forming or creating an electric circuit between the substrate 106 and die(s) 302 that can be stacked thereon.

After the traces 304 are formed on the substrate 106, a layer of solder resist material 306 can be placed on the substrate 106 and traces 304. Typically, the solder resist material 306 can make the surface of the substrate 106 more flat than if no solder resist material 306 were applied to the substrate 106 and traces 304; however, even with the solder resist material 306, the surface of the substrate 106 can still be uneven and can have ridges, higher regions, and lower regions, for example, as the traces 304 can be raised above the other surface areas of the substrate 106. Such uneven areas of the substrate 106 can cause delamination problems when attaching a die (e.g., 302) to the substrate 106. To reduce or minimize such delamination issues, die-attach film 108 can be used to facilitate attaching the die 302 to the substrate 106.

The die 302 can be adhered to the side of the substrate 106 having the traces 304 using die-attach film 108. The film 108 can be applied to the bottom (e.g., non-active side) of the die 302, and the die 302 can then be adhered to substrate 106. To facilitate adhering the die 302 to the substrate 106, heat can be applied to the film 108, and/or pressure can be applied to the die 302 and/or film 108, so that the film 108 can be malleable such that the film 108 can mold itself around the traces and can form a bond with the substrate 106 such that there are no gaps, or substantially no gaps, between the film 108 and the die 302 and between the film 108 and the substrate 106 and traces formed thereon.

In accordance with one aspect of the disclosed subject matter, the heat can be applied to the die 302 and the heat can be transferred to the film 108 via the die 302. The heat can be applied this way so long as the die 302 is not harmed by the application of such heat to the die 302. In accordance with another aspect of the disclosed subject matter, when the die 302 may be harmed by the application of such heat, the heat can be applied directly to the film 108. The film 108 can be applied such that it can reduce or eliminate delamination between the die 302 and the substrate 106 as well as the traces 304 and solder resist material 306 thereon. Once the die 302 is attached to the substrate 106, the heat and/or pressure can be removed to allow the film 108 to cure (e.g., soft cure). Further curing (e.g., application of heat) can be performed as desired to facilitate the attachment of the die 302 and the substrate 106.

The die 302 can then have wires (e.g., 110) (not shown) bonded onto the die 302, as desired, to electrically connect the die 302 to the substrate 106. The desired number of wires can be connected electrically to the substrate 106 by bonding one end of each of the wires correspondingly to the desired traces on the substrate 106. The other end of each of the wires 110 can be bonded correspondingly to pads (not shown) on the active side of the die 302.

It should be noted that, while device 300 is shown in FIG. 3 with no wires, die 302 can be wirebonded to have any desired number of wires 110. It should also be noted that well known structures have not been shown in order not to unnecessarily obscure the subject innovation.

Device 300, device 200, and/or device 100 can be included in most any electronic device that includes a semiconductor chip (e.g., device 300, device 200, device 100). Examples of such an electronic device can include a computer, a personal digital assistant (PDA), a cellular phone, a digital phone, an answering machine, a video device, a television, a digital versatile diskplayer/recorder, a music player/recorder, an MP3 player, a digital recorder, a digital camera, a microwave oven, an electronic organizer, an electronic toy, an electronic game, a scanner, a reader, a printer, a copy machine, or a facsimile machine.

Further, device 300, device 200, and/or device 100 can be a memory device, including non-volatile memory, such as flash memory, read only memory (ROM), programmable ROM (PROM), erasable programmable read only memory (EPROM), electronically erasable programmable read only memory (EEPROM), and the like; and volatile memory such as random access memory (RAM), including static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

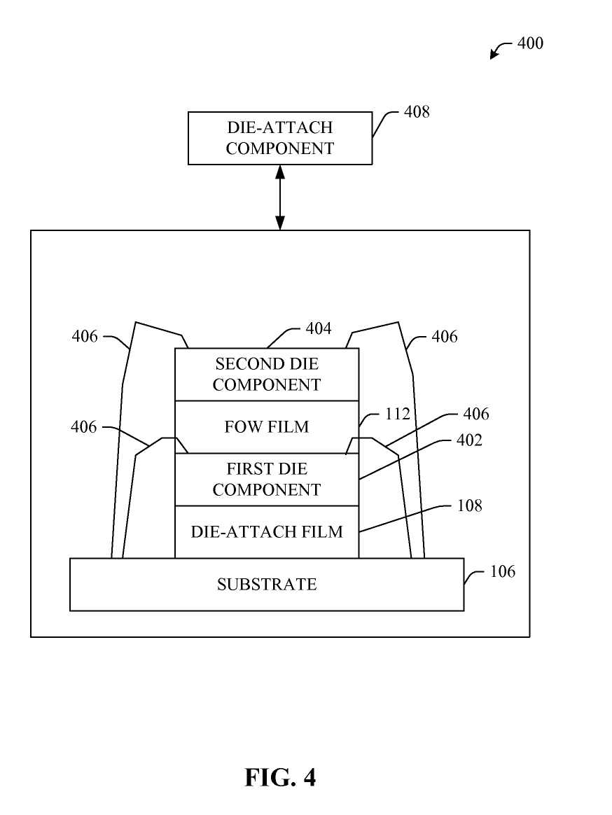

FIG. 4 illustrates a block diagram of a system 400 that facilitates forming a semiconductor device in accordance with the disclosed subject matter. System 400 can include a substrate component 106 that can be a substrate that can have traces formed thereon, where the traces can be formed on the substrate component 106 as previously disclosed herein. Substrate 106 can be associated with die-attach film 108 that can be a non-conductive adhesive material that be utilized to facilitate attaching a first die component 402 to the substrate component 106 and can facilitate attaching a second die component 404 to the first die component 402, as further described herein.

Each of first die component 402 and second die component 404 can have an active side and a non-active side, where pads (not shown) can be formed on the active side to facilitate wirebonding to electrically connect each of the first die component 402 and the second die component 404 to the substrate component 106. First die component 402, second die component 404, and substrate component 106 can be associated with wire component 406 which can be comprised of one or more wires (e.g., 110), as desired, to electrically connect traces on substrate component 106 to the pads formed on first die component 402 and/or second die component 404.

System 400 can further include a die attachment component 408 that can facilitate attachment of the first die component 402 to the substrate component 106 and the second die component 404 to the first die component 402. To attach the first die component 402 to the substrate component 106, die-attachment component 408 can facilitate applying die-attach film 108 to the non-active side (e.g., bottom side) of the first die component 402. Die-attach component 408 can apply a desired level of heat and a desired level of pressure to facilitate attachment of the first die component 402 to the substrate component 106 such that the die-attach film 108 can become semi-fluid or in a softened state so that the film 108 can mold itself around the traces associated with substrate component 106 without damaging the traces, or the other components (e.g., 106).

Further, die-attachment component 408 can facilitate attaching the second die component 404 to the first die component 402. Die-attachment component 408 can facilitate applying FOW film 112 to the non-active side (e.g., bottom side) of the second die component 404. Die-attach component 408 can apply a desired level of heat and a desired level of pressure to facilitate attachment of the second die component 404 to the first die component 402 and embedding of the wires 406 associated with the first die component 402 such that FOW film 112 can become semi-fluid or be in a softened state so that FOW film 112 can mold itself around the wires 406 bonded to the first die component 402 to embed the wires 406 in the FOW film 112 without causing damage to the wires 406 or the other components (e.g., 402).

In accordance with one embodiment of the disclosed subject matter, the die-attach component 408 can facilitate applying heat to the die-attach film 108 or FOW film 112, depending on which film is being used, by applying the heat to the die (e.g., 302, 204, 104) that has the film (e.g., 108 or 112) applied on its bottom side, where the heat can be transferred to the film (e.g., 108 or 112) via the die. The heat can be applied to the die so long as such heat will not cause harm to the die. In accordance with another embodiment of the disclosed subject matter, the die-attach component 408 can facilitate applying heat directly to the film (e.g., 108 or 112). For example, applying the heat directly to the film (e.g., 108 or 112) can be performed when applying heat to a die may cause harm to the die.

Die-attachment component 408 can further facilitate curing of the die-attach film 108 to facilitate the attachment of the first die component 402 to the substrate component 106 as well as the curing of the FOW film 112 to facilitate the attachment of the second die component 404 to the first die component 402. Die-attach component 408 can employ soft curing (e.g., letting the components set at room temperature) and/or hard curing (e.g., applying heat, such as by placing components in an oven), as desired, to facilitate such attachments of the components 106, 402, 404, for example.

In accordance with one embodiment of the disclosed subject matter, the first die component 402 can be a size that is the same as or similar to the size of the second die component 404 and die components 402, 404 can be adjacent to each other in the die stack with the second die component 404 being positioned above the first die component 402. The first die component 402 can be attached to the substrate component 106 by applying die-attach film 108 to the bottom side of the first die component 402 and utilizing the die-attach component 408 to facilitate attaching the first die component 402 to the substrate component 106. Wirebonding can be performed to attach the wires (e.g., 110) associated with the wire component 406 to the pads of the first die component 402 and the traces formed on the substrate component 106, as previously described. Since die components 402 and 404 are of the same or similar size, the pads and wires 406 associated with the first die component 402 do not extend beyond the surface area of the second die component 404 when the second die component 404 is attached on to the first die component 402.

To facilitate stacking the second die component 404 on top of the first die component 402 without damaging the wires 406 attached to the first die component 402, FOW can be employed by applying FOW film 112 to the bottom side (e.g., non-active side) of the second die component 404. Die-attach component 408 can facilitate applying heat and pressure to the FOW film component 112 to soften the film 112 such that the film 112 can mold itself around the wires 406 attached to the first die component 402 such that the wires 406 can be embedded in FOW film 112 and do not break, become unattached, or otherwise become impaired as the second die component 404 is placed and attached on top of the first die component 402 with the FOW film 112 sandwiched in between.

The thickness (e.g., height) of the FOW film 112 can be such that the wires 406 can be embedded in the film 112 with the film 112 extending in height beyond the high point of the wires 406 so that there is a buffer region between the top of the wires 406 and the bottom side of the second die component 404. For example, the wires 406 may extend to a height of sixty microns; in such an instance, the FOW film 112 can have a thickness of approximately seventy-five microns, so that the wires 406 can be embedded and there can be a buffer region of approximately fifteen microns beyond the top of the wires 406 and the bottom side of the second die component 404.

Wirebonding can be performed on the second die component 404 to electrically connect the substrate component 106 and the second die component 404 using wire component 406, as desired. Further, it should be noted that die-attach component 408 can facilitate curing the die-attach film 108 and FOW film 112 so that the attachment of respective components 106, 402, and 404 can be maintained and/or completed.

In accordance with another embodiment of the disclosed subject matter, the first die component 402 can be smaller in size (e.g., length, width, and/or height) than the second die component 404. System 400 can facilitate encapsulating a smaller die component (e.g., first die component 402) under a larger die component (e.g., second die component 404) and embedding the wires 406 attached to the smaller die component 402. The first die component 402 can be attached to the substrate 106 using die-attach film 108, as described herein. Further, wirebonding can be performed to attach wires associated with the wire component 406 to the first die component 402 and the substrate component 106, as described herein. A second die component 404 that can be significantly larger in surface area than the first die component 402 can be attached to the first die component 402 using FOW film component 112.

It should be noted that, without employing FOW film 112, the second die component 404 would have significant portions overhanging where the second die component 404 extends beyond the first die component 402. By employing FOW, film 112 can be applied to the bottom of the second die component 404 in such a thickness that the first die component 402 can be completely encapsulated in the FOW film 112, the wires 406 attached to the first die component 402 can be embedded in the FOW film 112, and the film 112 can extend from the bottom of the second die component 404 to the top of the substrate component 106 in those regions where the second die component 404 overhangs or extends beyond the surface area of the first die component 402. For example, if the first die component 402 plus the die-attach film 108 have a combined thickness of approximately 100 microns, FOW film 112 can be applied to the bottom side of the second die component 404 with a thickness of 170 microns to encapsulate the first die component 402 and embed the wires 406 bonded thereto.

Most any electronic device that can include a semiconductor chip can include system 400, or a portion thereof (e.g., components therein). Examples of such an electronic device can include a computer, a personal digital assistant (PDA), a cellular phone, a digital phone, an answering machine, a video device, a television, a digital versatile diskplayer/recorder, a music player/recorder, an MP3 player, a digital recorder, a digital camera, a microwave oven, an electronic organizer, an electronic toy, an electronic game, a scanner, a reader, a printer, a copy machine, or a facsimile machine.

Further, most any memory device can include system 400, or a portion thereof (e.g., components therein), including non-volatile memory, such as flash memory, read only memory (ROM), programmable ROM (PROM), erasable programmable read only memory (EPROM), electronically erasable programmable read only memory (EEPROM), and the like; and volatile memory such as random access memory (RAM), including static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

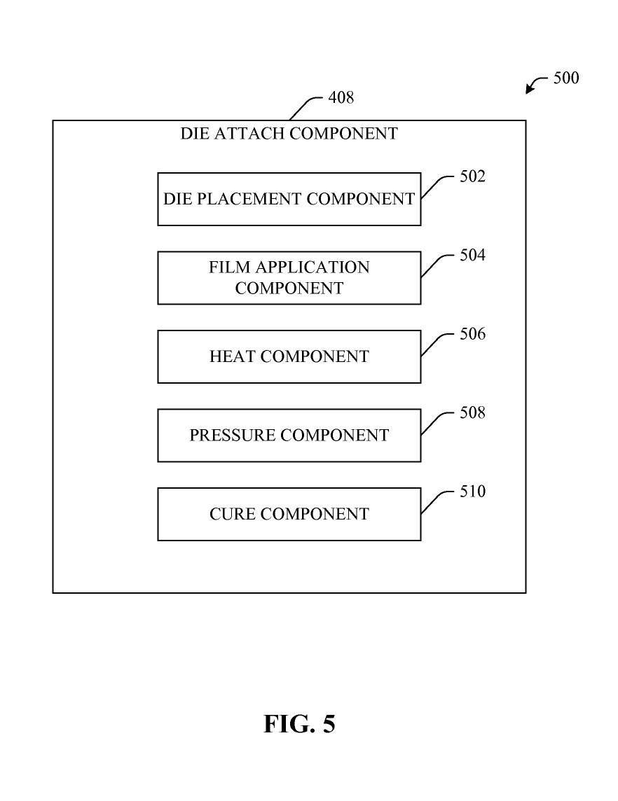

FIG. 5 is a block diagram 500 of a die-attach component 408 in accordance with an embodiment of the disclosed subject matter. Die-attach component 408 can include a die placement component 502 that can facilitate placing a die component (e.g., 402, 404) on a substrate component 106 or another die component, as desired. For example, die placement component 502 can be a die-attach tool that can pick up and hold a die component, and then place the die component on another die component or a substrate component 106, in accordance with the disclosed subject matter.

Die-attach component 408 can also include a film application component 504 that can facilitate applying die-attach film 108to the bottom of a die component (e.g., 402, 404) to facilitate attachment of the die component to a substrate component 106 and/or applying FOW film 112 to facilitate attachment of the die component on another die component and/or facilitate embedding wires bonded to the other die component within the FOW film 112.

Die-attach component 408 can further include a heat component 506 that can apply heat to the FOW film 112 during attachment of a die component to another die component and/or die-attach film 108 during attachment of a die component to a substrate 106. The heat component 506 can be applied at such a level so that the FOW film 112 can be in a softened or semi-fluid state such that the film 112 can mold itself around other components (e.g., wires 110, etc.) to attach the die component to the other die component so as to embed the wires bonded to the other die component within the FOW film 112 and to bond the die components together such that there are no gaps, or substantially no gaps, between the two die components, which can minimize or reduce delamination. Further, when attaching a die component to a substrate component 106, the heat can be applied such that the die-attach film 108 can mold itself around the traces formed on the substrate component 106 (as well as other uneven areas on the substrate component 106) such that there are no gaps, or substantially no gaps, between the die component and the substrate component 106, which can minimize or reduce delamination.

In accordance with one embodiment of the disclosed subject matter, the heat component 506 can apply heat to the die-attach film 108 and/or FOW film 112 by applying the heat to the die having the die-attach film 108 and/or FOW film 112 applied on its bottom side, where the heat can be transferred to the die-attach film 108 and/or FOW film 112 via the die. The heat can be applied to the die so long as such heat will not cause harm to the die. In accordance with another embodiment of the disclosed subject matter, the heat component 506 can apply heat directly to the die-attach film 108 and/or FOW film 112. For example, applying the heat directly to the die-attach film 108 and/or FOW film 112 can be performed when applying heat to a die may cause harm to the die.

Die-attach component 408 can include a pressure component 508 that can work in conjunction with the heat component 506 and/or the die placement component 502 to facilitate attaching a die component to another die component or the substrate component 106. When attaching a die component to the top side of another die component and embedding wires 406 bonded to the lower die component, the pressure can be applied to a die component, and as a result, to the FOW film 112 applied to the bottom of such die component (as well as heat from the heat component 506), in an amount that can facilitate attaching the die component to another die component thereunder such that the wires 406 attached to the other die component can be embedded within the FOW film 112 without the wires 406 breaking or becoming impaired in any way as well as attaching the two die components so that there are no gaps or voids to minimize delamination.

With regard to attaching a die component to the substrate component 106, the pressure component 508 can apply pressure to the die component (and the die-attach film 108 applied to the bottom side of the die component) such that the film 108 can mold itself around the traces formed on the substrate component 106 (and any other uneven areas of the substrate component 106) without causing harm to the traces or the substrate component 106 and to fill in all spaces so that there can be no gaps or voids between the die component and the substrate component 106, which can eliminate or reduce delamination. The die placement component 502, heat component 506, and/or pressure component 508 can facilitate removing the heat and/or pressure from the die component being attached and/or the film 108 applied thereto.

Die-attach component 408 can further comprise a curing component 510 that can facilitate curing the components (e.g., die-attach film 108, FOW film 112) during attachment of a die component to another die component or the substrate 106. Curing component 510 can facilitate soft curing, for example, just after the die component is attached to another component using FOW film 112. Curing component 510 can also employ other curing procedures, such as hard curing, to facilitate maintaining and/or completing the bonding or attachment of a die component to another component so that no gaps or voids exist between the die component, the die-attach film 108 and/or FOW film 112, and/or the other component attached thereto, in order to eliminate or reduce delamination.

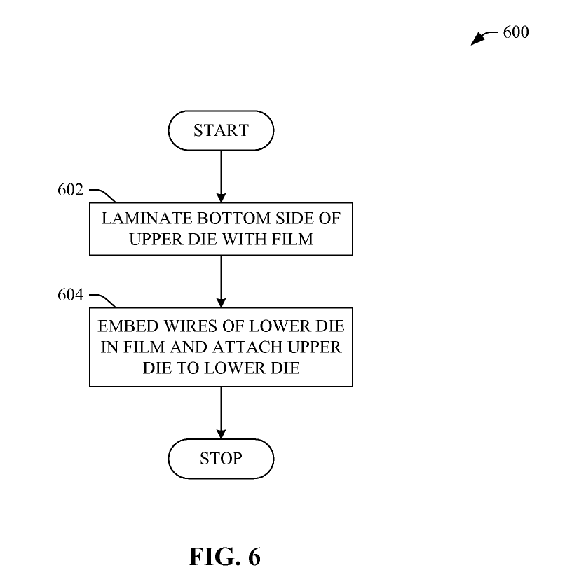

FIGS. 6-10 illustrate methodologies in accordance with the disclosed subject matter. For simplicity of explanation, the methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts may be required to implement the methodologies in accordance with the disclosed subject matter. In addition, those skilled in the art will understand and appreciate that the methodologies could alternatively be represented as a series of interrelated states via a state diagram or events. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

Referring to FIG. 6, a methodology 600 for attaching dies in accordance with the disclosed subject matter is illustrated. At 602, a die (e.g., upper die) can be laminated with FOW film 112 by applying film 112 to the bottom side of the upper die. The upper die can be the same size (e.g., length and/or width) as, similar in size to, or larger in size than another die (e.g., lower die) that is to be positioned below the upper die in a die stack, as more fully described below. At 604, the bottom side of the upper die can be adhered and/or attached to the top side of the lower die with wires bonded thereon and the wires bonded to the top side of the lower die can be embedded in the FOW film 112. The film 112 can be applied in such an amount so as to facilitate adhering and/or attaching the bottom side of the upper die to the top side of the lower die so that the wires bonded to the lower die can be embedded within the FOW film 112 and there is a buffer region of film 112 between the top of the wires of the lower die and the bottom side of the upper die. The dies can be attached with the FOW film 112 such that there are no gaps, or substantially no gaps, between the bottom side of the upper die and the top side of the lower die. At this point, methodology 600 can end.

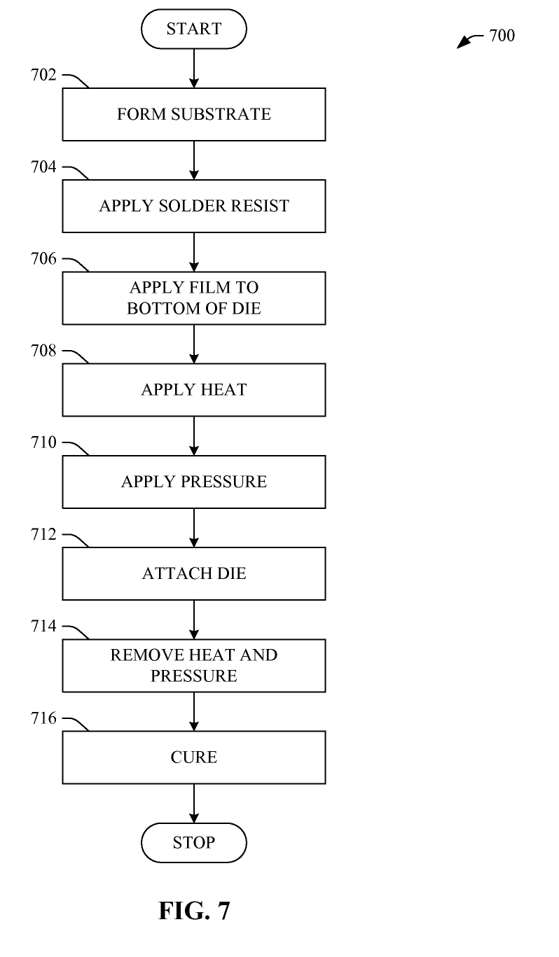

FIG. 7 illustrates a methodology 700 for attaching a die to a substrate in accordance with the disclosed subject matter. At 702, a substrate can be formed. The substrate can have traces formed thereon, for example. At 704, solder resist can be applied to the substrate and the traces formed thereon. At 706, die-attach film 108 can be applied to the bottom side (e.g., non-active side) of a die, which can have an active side and a non-active side. The die-attach film 108 can be applied in such an amount so as to facilitate filling in any uneven areas on the substrate, such as those from traces that can be raised areas on the substrate, and attachment of the die to the substrate, while minimizing the space used by the film 108 for efficient space utilization in multi-die packaging.

At 708, heat can be applied to the die-attach film 108 and/or the die to which the film 108 has been applied, where the heat can be transferred to the film 108. The heat can be applied at such a level so that the film 108 can be put in a soft or semi-fluid state so that the film 108 can mold itself to fill in any region or space on the substrate surface, such as by having the film 108 mold around the traces formed on the substrate. At 710, pressure can be applied to the film 108 and/or the die on which the film 108 has been applied. The pressure can be applied at such a level so as to move and mold the heated film 108 to fill in all spaces between the die and the substrate so that no gaps or voids exist between the die and the substrate, which can reduce or eliminate delamination or detachment of the die from the substrate. The amount of pressure can be such that it will not cause harm to the die, substrate, or other components associated therewith.

At 712, the die can be adhered and/or attached to the substrate. As stated, the bottom side of the die can be attached to the top side of the substrate using the die-attach film 108 such that no gaps or voids exist between the die and the substrate. At 714, once the die is adhered and/or attached to the substrate, the heat and pressure can be removed from the film 108 and/or die. At 716, the film 108 can be cured, such as by a soft curing process and/or a hard curing process. The curing can be such that no gaps or voids form during curing, so as to minimize delamination. At this point, methodology 700 can end.

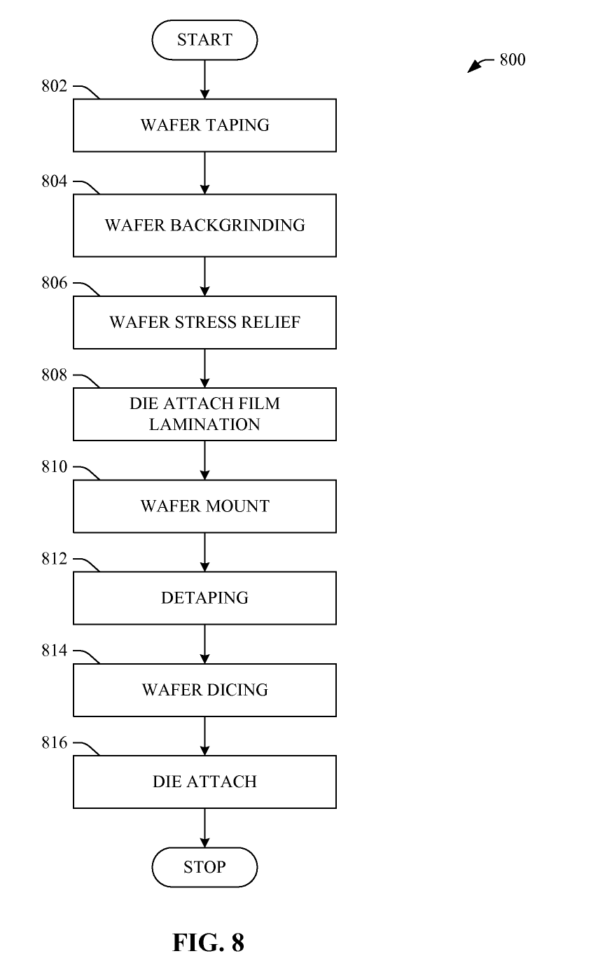

Referring to FIG. 8, another methodology 800 for attaching a die to a substrate in accordance with the disclosed subject matter is illustrated. At 802, a semiconductor wafer can be taped using conventional tape, such as backgrinding tape, that can be applied to the active side of the wafer. The taping of the wafer can be performed using a taping machine, for example. At 804, the wafer can be backgrinded by grinding the wafer on its non-active side, which can reduce the thickness of the wafer to a desired thickness. At 806, stress relief can be applied to the backgrinded wafer in order to remove any portions of the wafer that may have been damaged as a result of the wafer backgrinding. At 808, the non-active side of the wafer can be laminated using die-attach film 108. The amount of film 108 applied to the wafer can be such that it can facilitate attaching the wafer to the substrate and the film 108 can mold itself around traces and other uneven portions on the surface of the substrate. For example, die-attach film 108 having a thickness of thirty microns can be applied to the non-active side of the wafer.

At 810, the wafer can be mounted to a dicing tape. At 812, detaping can be performed to remove the tape applied to the wafer at 802. At 814, the wafer can be diced, as desired, to create one or more dies from the wafer. For example, a dicing saw can be utilized to dice the wafer into one or more dies. At 816, a die resulting from the diced wafer can be attached to the substrate by placing the laminated die on the top side of the substrate with the die-attach film 108 facilitating attaching the die to the substrate, in accordance with the disclosed subject matter. At this point, methodology 800 can end.

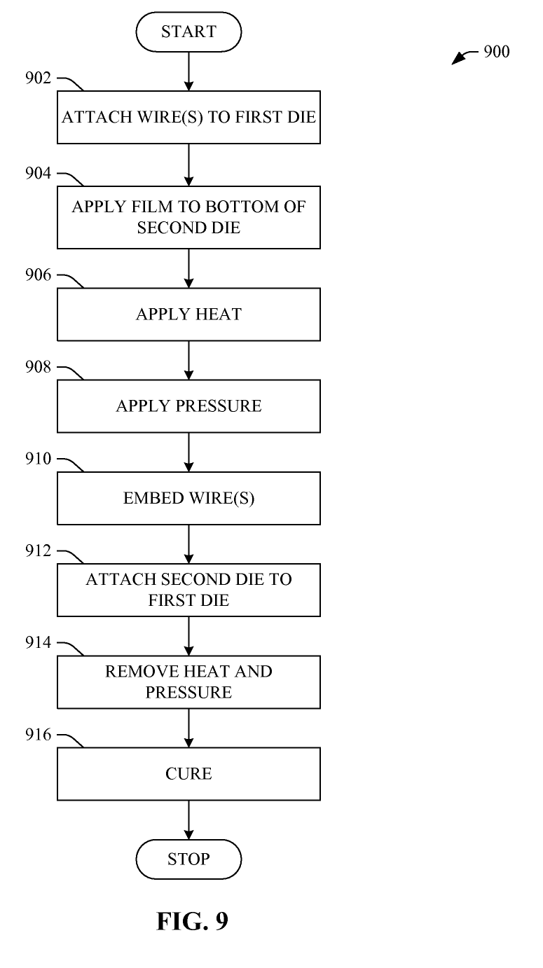

FIG. 9 depicts a methodology 900 for stacking dies in accordance with the disclosed subject matter. At 902, a number of wires can be attached to a first die. The number of wires can be chosen, as desired, to electrically connect the first die to a substrate, where one end of each of the wires can be bonded to respective pads on the active side of the first die and the other end of each of the wires can also be bonded to the desired traces on the substrate. At 904, FOW film 112 can be applied to the bottom side (e.g., non-active side) of a second die, which can have an active side and a non-active side. The FOW film 112 can be applied in such an amount so as to facilitate attachment of the second die on a top side of the first die, embedding the wires bonded onto the top side of the first die within the film 112, and providing a buffer region between the top of the wires bonded to the first die and the bottom side of the second die, while at the same time minimizing the space used by the film 112 between the dies for efficient space utilization in multi-die packaging.

At 906, heat can be applied to the FOW film 112 and/or the second die to which the film 112 has been applied, where such heat can be transferred to the film 112. The heat can be applied at such a level so that the film 112 can be put in a soft or semi-fluid state so that the film 112 can mold itself to around the wires bonded onto the first die. At 908, pressure can be applied to the film 112 and/or the second die on which the film 112 has been applied. The pressure can be applied at such a level so as to move and mold the heated film 112 to flow around the wires to embed the wires within the film 112 as well as to fill in any gaps or voids between the first die and the second die. The amount of pressure can be such that the pressure will not cause harm to the first die, second die, the wires, the substrate, and other components associated therewith.

At 910, the wires bonded onto the first die can be embedded within the film applied to the bottom side of the second die. At 912, the second die can be adhered and/or attached to the first die with the FOW film 112 facilitating the adhesion and/or attachment of the second die to the first die, as the film 112 can be molded around the wires bonded onto the first die to reach the top surface of the first die. As stated, the second die can be attached to the first die using the film 112 such that no gaps or voids exist between the second die and the first die in order to reduce or eliminate delamination of the dies. At 914, once the second die is attached to the first die, the heat and pressure can be removed from the film 112 and/or the second die. At 916, the film 112 can be cured, such as by a soft curing process and/or a hard curing process. The curing can be such that no gaps or voids form during curing, so as to minimize delamination of the dies. At this point, methodology 900 can end.

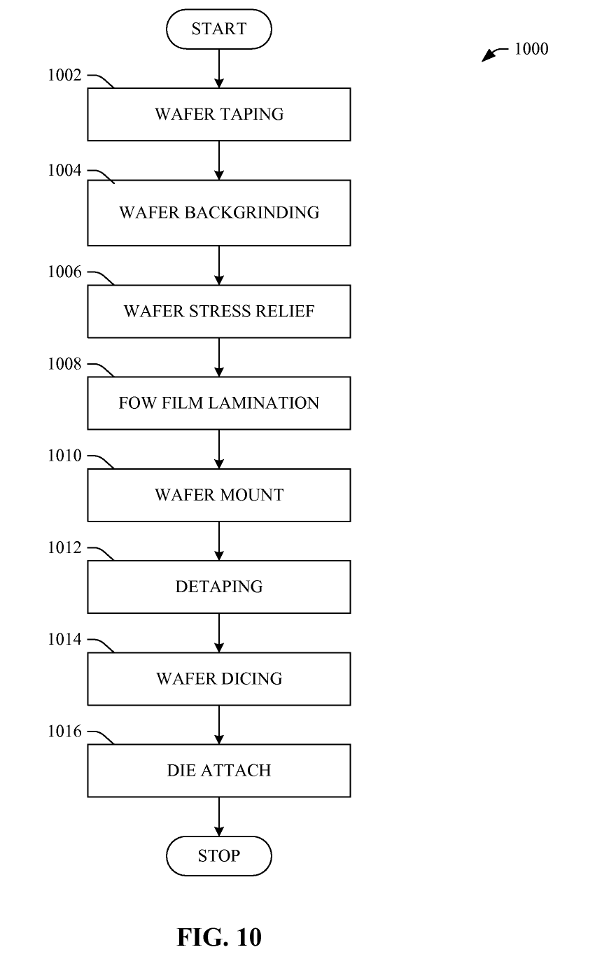

FIG. 10 depicts another methodology 1000 for stacking dies in accordance with the disclosed subject matter. At 1002, a semiconductor wafer can be taped using conventional tape, such as backgrinding tape, that can be applied to the active side of the wafer. The wafer taping can be performed using a taping machine, for example. At 1004, the wafer can be backgrinded by grinding the wafer on its non-active side and reducing the thickness of the wafer to a desired thickness. At 1006, stress relief can be applied to the backgrinded wafer in order to remove any portions of the wafer that may have been damaged as a result of the wafer backgrinding.

At 1008, the non-active side of the wafer can be laminated using FOW film 112. The amount of film 112 applied to the wafer can be such that it can facilitate adhering and/or attaching a die, which can ultimately be formed from the wafer, to another die situated under the laminated die to form a die stack as well as embed wires bonded onto the lower die such that the FOW film 112 can mold itself around the wires of the lower die, and further be of such a thickness so that there can be a buffer region between the bottom side of the laminated die and the top of the wires bonded onto the lower die. For example, film 112 having a thickness of approximately seventy-five microns can be applied to the non-active side of the wafer. The laminated die can be a size (e.g., length and/or width) that is similar to or the same as the lower die, or can be greater in size than the lower die such that the laminated die can have portions that overhang beyond the surface area of the lower die, for example.

At 1010, the wafer can be mounted to a dicing tape. At 1012, detaping can be performed to remove the wafer tape applied to the wafer at 1002. At 1014, the wafer can be diced, as desired, to create one or more dies from the wafer. A dicing saw can be utilized to dice the wafer into one or more dies, for example. At 1016, a die formed from the diced wafer can be attached to another die by placing the laminated die on top of a lower die with the FOW film 112 facilitating attaching the two dies and embedding the wires bonded onto the lower die, in accordance with the disclosed subject matter. At this point, methodology 1000 can end.

As utilized herein, terms “component,” “system,” and the like can include a computer-related entity, either hardware, software (e.g., in execution), and/or firmware. For example, a component can be a process running on a processor, a processor, an object, an executable, a program, and/or a computer. By way of illustration, both an application running on a server and the server can be a component. One or more components can reside within a process and a component can be localized on one computer and/or distributed between two or more computers.

Although the subject innovation has been shown and described with respect to certain illustrated aspects, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure, which performs the function in the herein illustrative aspects of the disclosed subject matter. In this regard, it will also be recognized that the subject innovation can include a system as well as a computer-readable medium having computer-executable instructions for performing the acts and/or events of the various methods of the subject innovation.

What has been described above includes examples of aspects of the disclosed subject matter. It is, of course, not possible to describe every conceivable combination of components or methodologies for purposes of describing the disclosed subject matter, but one of ordinary skill in the art may recognize that many further combinations and permutations of the disclosed subject matter are possible. Accordingly, the disclosed subject matter is intended to embrace all such alterations, modifications and variations that fall within the spirit and scope of the appended claims. Furthermore, to the extent that the terms “includes,” “has,” or “having,” or variations thereof, are used in either the detailed description or the claims, such terms are intended to be inclusive in a manner similar to the term “comprising” as “comprising” is interpreted when employed as a transitional word in a claim.

What is claimed is:

1. A semiconductor device, comprising:
a first die; and
a second die, the second die is stacked on top of the first die and a bottom side of the second die is adhered to a top side of the first die using a film, and the second die is one of a same size, substantially the same size, or a larger size, in at least one of length or width, or a combination thereof, as compared to the first die.

2. The device of claim 1, further comprising:
a substrate having a plurality of traces formed thereon; and
a plurality of wires that are electrically connected correspondingly to the substrate and at least one of the first die and the second die, or a combination thereof.

3. The device of claim 2, the plurality of wires electrically connected to the first die are embedded in the film.

4. The device of claim 3, the film is of a thickness such that there is a buffer region between the bottom side of the second die and a top portion of each of the plurality of wires connected to the first die.

5. The device of claim 2, the first die is adhered to the substrate using the film such that there are no gaps between the first die and the substrate.

6. The device of claim 2, the second die is larger in size than the first die, and the film is of a thickness such that the first die and the plurality of wires connected thereto are embedded in the film with a buffer region between the bottom of the second die and a top portion of each of the plurality of wires.

7. An electronic product comprising the device of claim 1, the electronic product further comprising at least one of a computer, a personal digital assistant, a cellular phone, a digital phone, an answering machine, a video device, a television, a digital versatile diskplayer/recorder, a music player/recorder, an MP3 player, a digital recorder, a digital camera, a microwave oven, an electronic organizer, an electronic toy, an electronic game, a scanner, a reader, a printer, a copy machine, or a facsimile machine.

8. A system that facilitates attaching a die component to another die component or a substrate, comprising:
a first die component; and
at least one other component, the at least one other component is at least one of a second die component or a substrate component, the first die component is attached to the at least one other component using a film applied to the bottom side of the first die component.

9. The system of claim 8, further comprising:
one or more wires, the one or more wires are bonded to the second die component; and
a die attach component that facilitates application of at least one of heat or pressure, or a combination thereof, to at least one of the first die component or the film, or a combination thereof, to facilitate attachment of the first die component to the second die component, and to embed the one or more wires in the film.

10. The system of claim 9, the second die component is a size that is the same or similar to the size of the first die component.

11. The system of claim 9, the second die component is a size that is smaller than the first die component, the first die component is stacked on top of the second die component, and the second die component is embedded in the film.

12. The system of claim 11, the die attach component facilitates application of at least one of heat or pressure, or a combination thereof, to at least one of the second die component or the film, or a combination thereof, to facilitate attaching the second die component to the substrate component such that no voids exist between the second die component and the substrate.

13. A memory device comprising the system of claim 8, the memory device comprising non-volatile memory or volatile memory, or a combination thereof, the non-volatile memory comprising flash memory, read only memory (ROM), programmable ROM, erasable programmable ROM, electronically erasable programmable ROM, the volatile memory comprising random access memory (RAM), static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

14. A method for attaching a die to another die or a substrate, comprising:
laminating the bottom of the die with a film; and
attaching the die to at least one of the other die or the substrate, or a combination thereof.

15. The method of claim 14, further comprising:
attaching one or more wires to the die and the substrate to electrically connect the die and the substrate;
laminating the bottom side of the other die with the film;
applying at least one or heat or pressure, or a combination thereof, to at least one of the other die or the film, or a combination thereof;
embedding the one or more wires in the film; and
attaching the bottom side of the other die to the top side of the die.

16. The method of claim 15, further comprising:
removing the at least one of heat or pressure, or a combination thereof, after the one or more wires have been embedded in the film; and
curing the film.

17. The method of claim 15, further comprising:
embedding the die within the film, when the die is smaller than the other die.

18. The method of claim 15, further comprising:
transferring the heat to the film via the other die, when the heat is applied to the other die.

19. The method of claim 14, further comprising:
applying a film to the bottom side of the die;
applying at least one or heat or pressure, or a combination thereof, to at least one of the die or the film, or a combination thereof;
attaching the die to the substrate;
removing the at least one of heat or pressure, or a combination thereof, after the die is attached to the substrate such that no gaps exist between the die and the substrate; and
curing the film.

20. The method of claim 14, further comprising:
taping a wafer;
backgrinding the wafer;
applying stress relief to the wafer;
mounting the wafer;
detaping the wafer; and
dicing the wafer into one or more dies.
